(19) United States
(12) Patent Application Publication
(10) Pub. No.: US 2025/0306121 A1
(43) Pub. Date: Oct. 2, 2025

(54) SUPERCAPACITOR STATE-OF-HEALTH ESTIMATION SYSTEM AND A METHOD THEREOF

(71) Applicants: HYUNDAI MOTOR COMPANY, Seoul (KR); KIA CORPORATION, Seoul (KR); UIF (University Industry Foundation), Yonsei University, Seoul (KR)

(72) Inventors: Young Woo Noh, Guri-si (KR); Jong Moon Chung, Seoul (KR); Jeong Eon Park, Yongin-si (KR)

(73) Assignees: HYUNDAI MOTOR COMPANY, Seoul (KR); KIA CORPORATION, Seoul (KR); UIF (University Industry Foundation), Yonsei University, Seoul (KR)

(21) Appl. No.: 18/825,777

(22) Filed: Sep. 5, 2024

(30) Foreign Application Priority Data
Apr. 2, 2024 (KR) 10-2024-0044854

(51) Int. Cl. G01R 31/392; G01R 31/36; G01R 31/367; G01R 31/3842

(52) U.S. Cl. CPC G01R 31/392; G01R 31/3646; G01R 31/367; G01R 31/3842

(57) ABSTRACT

A system and a method for supercapacitor state-of-health (SoH) estimation. The system includes: a data detector that monitors charge-discharge data of a supercapacitor mounted in a vehicle; a vehicle controller including a data construction unit that constructs a time series data matrix for each charge/discharge cycle of the supercapacitor based on the charge-discharge data monitored by the data detector, and a neural network model that estimates SoH of the supercapacitor using the time series data matrix for each charge-discharge cycle of the supercapacitor output from the data construction unit; and a display device that displays an estimation result for the SoH of the supercapacitor estimated by the neural network model of the vehicle controller.

### CROSS-REFERENCE TO RELATED APPLICATION

This application claims, under 35 U.S.C. § 119(a), the benefit of and priority to Korean Patent Application No. 10-2024-0044854 filed on Apr. 2, 2024, the entire contents of which are incorporated herein by reference.

### BACKGROUND

### (a) Technical Field

The present disclosure relates to a state-of-health (SoH) estimation system and a method of SoH estimation. More particularly, the present disclosure relates to a SoH estimation system and a method of SoH estimation, capable of accurately estimating SoH of a supercapacitor.

### (b) Background Art

A supercapacitor is a kind of energy storage system having a capacity capable of storing a large amount of electric charge compared with a typical capacitor. Such a supercapacitor has a long life and a high power density based on a non-faradic process, and high power discharging and fast charging characteristics. Thus, this type of supercapacitor may be useful as an auxiliary energy source for vehicles.

Accordingly, research and development are underway to apply such a supercapacitor to vehicles for the purpose of improving vehicle fuel efficiency and providing power assistance.

The supercapacitor has a characteristic that SoH is shortened as it is used longer and as charging and discharging are repeated. As a result, the capacity and performance thereof may gradually degrade.

Since the degradation of the supercapacitor shows significant nonlinearity and is affected by various factors, durability and SoH evaluation is essential for stable power operation.

Therefore, to determine when a supercapacitor needs to be replaced, and to minimize the negative effects that may occur due to decrease in the capacity and performance of the supercapacitor, a method of accurately estimating SoH (State of Health) has been demanded in the art.

The above information disclosed in this Background section is only for enhancement of understanding of the background of the disclosure and therefore it may contain information that does not form the prior art that is already known to a person having ordinary skill in the art.

### SUMMARY

The present disclosure has been made in an effort to solve the above-described problems, and an object of the present disclosure is to provide a system and method for supercapacitor state-of-health (SoH) estimation, capable of accurately estimating SoH of a supercapacitor using a multi-graph learning algorithm and a many-to-many recurrent neural network model.

In one aspect, an embodiment of the present disclosure provides a supercapacitor state-of-health (SoH) estimation system. The system includes: a data detector that monitors charge/discharge data (i.e., charge-discharge data) of a supercapacitor mounted in a vehicle; a vehicle controller including a data construction unit that constructs a time series data matrix for each charge/discharge cycle (i.e., charge-discharge cycle) of the supercapacitor based on the charge/discharge data monitored by the data detector, and a neural network model that estimates SoH of the supercapacitor using the time series data matrix for each charge/discharge cycle of the supercapacitor output from the data construction unit; and a display device that displays an estimation result for the SoH of the supercapacitor estimated by the neural network model of the vehicle controller.

In an embodiment, the system may further include: a data server that stores the time series data matrix for each charge/discharge cycle of the supercapacitor transmitted from the vehicle controller; and a neural network model constructing processor configured to construct a neural network model using the time series data matrix for each charge/discharge cycle of the supercapacitor stored in the data server and to provide the constructed neural network model to the vehicle controller.

In another embodiment, the neural network model may be constructed using at least one of a many-to-many type Long Short-Term Memory (LSTM), a Gated Recurrent Unit (GRU), a Recurrent Neural Network (RNN) model, or a combination thereof.

In an embodiment, the neural network model may include: a first stacked GRU layer that has a plurality of gated recurrent units (GRU) stacked in a recurrent neural network arrangement, and determines a hidden state value for each time step using a first input value including a voltage decrease value, a discharge current and a temperature of the supercapacitor. The neural network model may further include: a self-attention layer that calculates an attention value using the hidden state value for each time step of the first stacked GRU layer; and a concatenation layer that determines a second input value by combining the attention value calculated in the self-attention layer with the hidden state values of the first stacked GRU layer. The neural network model may further include: a second stacked GRU layer that has a plurality of gated recurrent units stacked in a recurrent neural network arrangement, and determines a hidden state value for each time step using the second input value; and a time-distributed layer that calculates a final result for estimating the SoH of the supercapacitor by multiplying the hidden state value for each time step of the second stacked GRU layer by a weight and outputs the final result.

In another aspect, an embodiment of the present disclosure provides a supercapacitor state-of-health (SoH) estimation method. The method includes: monitoring, by a data detector, charge/discharge data of a supercapacitor mounted in a vehicle; and constructing, by a data construction unit of a vehicle controller, a time series data matrix for each charge/discharge cycle of the supercapacitor based on the charge/discharge data monitored by the data detector. The method further includes: estimating, by a neural network model of the vehicle controller, SoH of the supercapacitor based on the time series data matrix for each charge/discharge cycle of the supercapacitor constructed by the data construction unit; and displaying, on a display device, an estimation result for the SoH of the supercapacitor estimated by the neural network model of the vehicle controller.

In an embodiment, the method may further include: displaying, when an estimated capacity decrease value is less than a threshold value, an alarm indicating that the supercapacitor needs to be replaced is displayed on the display device. The estimated capacity decrease value is the estimation result for SoH of the supercapacitor estimated by the neural network model of the vehicle controller.

In an embodiment, the method may further include: storing, in a data server, the time series data matrix for each charge/discharge cycle of the supercapacitor transmitted from the vehicle controller; constructing, by a neural network model constructing processor, a neural network model based on the time series data matrix for each charge/discharge cycle of the supercapacitor stored in the data server; and providing the constructed neural network model to the vehicle controller.

In an embodiment, constructing the neural network model may include: dividing neural network model construction data into training data, verification data, and test data; selecting input features for training the neural network model from the training data and the verification data; performing standard scaling for the selected input features; executing a multi-graph learning algorithm for generating a final training matrix based on the standard-scaled input features; and performing training of the neural network model for estimating the SoH of the supercapacitor using the final training matrix obtained using the multi-graph learning algorithm.

In an embodiment, constructing the neural network model may include: selecting the input features for training the neural network model from the test data; performing the standard scaling for the selected input features to generate a test input matrix; inputting the test input matrix to the neural network model for which the training is completed; outputting, from the training-completed neural network model, an estimated capacity decrease value of the supercapacitor, as a result of training about the test input matrix; evaluating performance of the training-completed neural network model based on the estimated capacity decrease value of the supercapacitor output from the training-completed neural network model; confirming whether a desired performance of the training-completed neural network model has been achieved based on the estimated capacity decrease value of the supercapacitor output from the training-completed neural network model; and storing the training-completed neural network model for which a determination is made that the desired performance has been achieved.

In an embodiment, evaluating the performance of the training-completed neural network model may include: determining that the desired performance of the training-completed neural network model has been achieved, when a difference between the capacitance, which is the estimated capacity decrease value of the supercapacitor output from the training-completed neural network model, and an actual capacitance of the supercapacitor determined through a predetermined test are within a preset error range.

In an embodiment, when the capacitance, which is the estimated capacity decrease value of the supercapacitor output from the training-completed neural network model, is different from the actual capacitance of the supercapacitor determined through the predetermined test over the preset error range, hyperparameter tuning is performed, and training of the neural network model is performed again.

In an embodiment, executing the multi-graph learning algorithm includes: generating a time series data matrix having standard-scaled input features based on a sliding window method in a first data sequence; and stacking the generated time series data matrix on a previous time series data matrix generated from a previous data file to generate the final training matrix.

In an embodiment, after generating the time series data matrix is completed, a size of a remaining data sequence and a size of a data window sequence to be formed are compared, and when the size of the remaining data sequence is equal to or greater than the size of the data window sequence to be formed, generating the time series data matrix is repeated based on the sliding window method.

In an embodiment, the training-completed neural network model may include: a first stacked GRU layer that has a plurality of gated recurrent units (GRU) stacked in a recurrent neural network arrangement, and determines a hidden state value for each time step using a first input value including a voltage decrease value, a discharge current and a temperature of the supercapacitor; a self-attention layer that calculates an attention value using the hidden state value for each time step of the first stacked GRU layer; a concatenation layer that determines a second input value by combining the attention value calculated in the self-attention layer with the hidden state values of the first stacked GRU layer; a second stacked GRU layer that has a plurality of gated recurrent units stacked in a recurrent neural network arrangement, and determines a hidden state value for each time step using the second input value; and a time-distributed layer that calculates a final result for estimating the SoH of the supercapacitor by multiplying the hidden state value for each time step of the second stacked GRU layer by a weight and outputs the final result.

Other aspects and embodiments of the disclosure are discussed below.

It is to be understood that the term “vehicle” or “vehicular” or other similar terms as used herein are inclusive of motor vehicles in general such as passenger automobiles including sport utility vehicles (SUV), buses, trucks, various commercial vehicles, watercraft including a variety of boats and ships, aircraft, and the like, and includes hybrid vehicles, electric vehicles, plug-in hybrid electric vehicles, hydrogen-powered vehicles and other alternative fuel vehicles (e.g., fuels derived from resources other than petroleum). As referred to herein, a hybrid vehicle is a vehicle that has two or more sources of power, for example, vehicles powered by both electricity and gasoline.

The above and other features of the disclosure are discussed below.

### BRIEF DESCRIPTION OF THE DRAWINGS

The above and other features of the present disclosure are described in detail with reference to certain embodiments thereof illustrated the accompanying drawings which are given herein below by way of illustration only, and thus are not limitative of the present disclosure, and wherein:

FIG. 1 is a configuration diagram showing a supercapacitor SoH estimation system according to an embodiment of the present disclosure;

FIG. 2 is a flowchart showing a supercapacitor SoH estimation method according to an embodiment of the present disclosure;

FIGS. 3 and 4 are flowcharts showing a neural network model construction method used in a supercapacitor SoH estimation method according to an embodiment of the present disclosure;

FIG. 5 is a conceptual diagram showing a many-to-many configuration method used in a supercapacitor SoH estimation method according to an embodiment of the present disclosure;

FIG. 6 is a conceptual diagram showing an example of a neural network model used in a supercapacitor SoH estimation method according to an embodiment of the present disclosure;

FIG. 7 is a conceptual diagram showing another example of a neural network model used in a supercapacitor SoH estimation method according to an embodiment of the present disclosure;

FIG. 8 is a structural diagram showing a construction example of a neural network model used in a supercapacitor SoH estimation method according to an embodiment of the present disclosure; and

FIGS. 9 and 10 are graphs showing results of comparing capacitance of a supercapacitor output from a neural network model learned for a supercapacitor SoH estimation method according to an embodiment of the present disclosure with actual capacitance.

It should be understood that the appended drawings are not necessarily to scale, presenting a somewhat simplified representation of various features illustrative of the basic principles of the disclosure. The specific design features of the present disclosure as disclosed herein, including, for example, specific dimensions, orientations, locations, and shapes will be determined in part by the particular intended application and use environment. The drawings described herein are for illustration purposes only and are not intended to limit the scope of the present disclosure.

In the figures, reference numbers refer to the same or equivalent parts of the present disclosure throughout the several figures of the drawing.

### DETAILED DESCRIPTION

Hereinafter, reference is made in detail to various embodiments of the present disclosure, examples of which are illustrated in the accompanying drawings and described below. While the disclosure is described in conjunction with embodiments, it should be understood that the present description is not intended to limit the disclosure to the embodiments. On the contrary, the disclosure is intended to cover not only the embodiments, but also various alternatives, modifications, equivalents and other embodiments, within the spirit and scope of the disclosure as defined by the appended claims.

It should be understood that, although the terms “first”, “second”, and the like may be used herein to describe various elements, these elements should not be limited by these terms. These terms are only used to distinguish one element from another. For example, a first element may be termed a second element, and, similarly, a second element may be termed a first element, without departing from the scope of the embodiments of the present disclosure.

In addition, it should be understood that, when an element is “connected” or “coupled” to another element, it may be directly connected or coupled to the other element, or may be indirectly connected or coupled to the other element with a different element being interposed therebetween. In contrast, when an element is “directly connected” or “directly coupled” to another element, this means that there is no intervening element therebetween. Other words used to describe the relationship between elements should be interpreted in a similar manner (for example, “between” and “directly between”, “adjacent” and “directly adjacent”, and the like).

Wherever possible, the same reference numbers are used throughout the drawings to refer to the same or like parts. The terminology used herein is for the purpose of describing particular embodiments only and is not intended to limit embodiments of the disclosure. As used herein, the singular forms “a”, “an”, and “the” are intended to include the plural forms as well, unless the context clearly indicates otherwise. It should be further understood that the terms “comprise”, “include”, and “have” used herein specify the presence of stated components, steps, operations, and/or elements, but do not preclude the presence or addition of one or more other components, steps, operations, and/or elements.)

When a component, controller, processor, device, element, apparatus, or the like of the present disclosure is described as having a purpose or performing an operation, function, or the like, the component, controller, processor, device, element, apparatus, or the like should be considered herein as being “configured to” meet that purpose or to perform that operation or function.

In the present disclosure, each of phrases such as “A or B”, “at least one of A and B”, “at least one of A or B”, “A, B or C”, “at least one of A, B and C”, “at least one of A, B or C” and “at least one of A, B, or C, or a combination thereof” may include any one or all possible combinations of the items listed together in the corresponding one of the phrases.

The term “unit” or “module” used in this specification signifies one unit that processes at least one function or operation, and may be realized by hardware, software, or a combination thereof. The operations of the method or the functions described in connection with the forms disclosed herein may be embodied directly in a hardware or a software module executed by a processor, or in a combination thereof.

Hereinafter, embodiments of the present disclosure are described in detail with reference to the accompanying drawings.

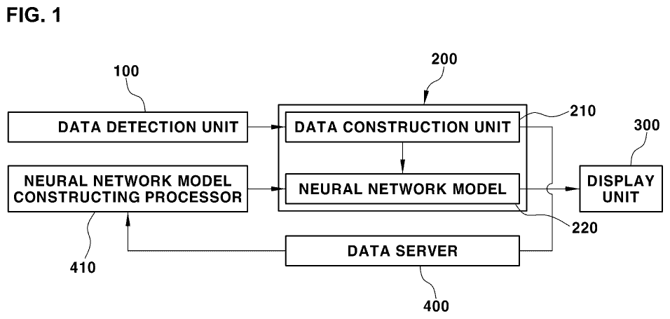

FIG. 1 is a configuration diagram showing a supercapacitor SoH estimation system according to an embodiment of the present disclosure.

As shown in FIG. 1, the supercapacitor SoH estimation system according to an embodiment of the present disclosure includes a data detector 100, a vehicle controller 200 that includes a data construction unit 210 and a neural network model 220, a display device 300, and the like.

The data detector 100 is configured to detect charge/discharge data of a supercapacitor mounted in a vehicle. The data detector 100 may be a sensor that detects charge/discharge data of the supercapacitor such as voltage, current, temperature, and the like, or may be a battery management system (BMS) or a capacitor management system (CMS) that monitors the charge/discharge data of the supercapacitor such as voltage, current, temperature, and the like.

The vehicle controller 200 may include the data construction unit 210 that constructs a time series data matrix for each charge/discharge cycle of the supercapacitor based on the charge/discharge data monitored by the data detector 100, and the neural network model 220 that estimates SoH of the supercapacitor using the time series data matrix for each charge/discharge cycle of the supercapacitor output from the data construction unit 210.

The display device 300 displays an estimation result for SoH of the supercapacitor estimated by the neural network model 220 of the vehicle controller 200. The display device 300 may be a display mounted inside the vehicle.

With this configuration, while the vehicle is being driven on a road, a process of detecting the charge/discharge data of the supercapacitor mounted in the vehicle to provide the detection result to the vehicle controller 200, by the data detector 100, a process of constructing the time series data matrix for each charge/discharge cycle of the supercapacitor based on the charge/discharge data monitored by the data detector 100, by the data construction unit 210 of the vehicle controller 200, a process of estimating SoH of the supercapacitor using the time series data matrix for each charge/discharge cycle of the supercapacitor output from the data construction unit 210, by the neural network model 220 of the vehicle controller 200, and a process of displaying, in a case where the estimated SoH of the supercapacitor is less than a threshold, an alarm indicating that the supercapacitor needs to be replaced on the display device 300, may be performed.

The supercapacitor SoH estimation system according to an embodiment of the present disclosure may further include a data server 400 for constructing a neural network and a neural network model constructing processor 410.

The data server 400 is communicatively connected to the vehicle controller 200, is provided in a predetermined control center, and the like, and stores the charge/discharge data (voltage, current, temperature, and the like) of the supercapacitor transmitted from the vehicle controller 200 and the time series data matrix for each charge/discharge cycle of the supercapacitor constructed by the data construction unit 210.

The neural network model constructing processor 410 constructs the neural network model 220 using the time series data matrix for each charge/discharge cycle of the supercapacitor and the charge/discharge data (voltage, current, temperature, and the like) of the supercapacitor stored in the data server 400, and provides the constructed neural network model to the vehicle controller 200.

The neural network model 220 may be provided as one selected from a many-to-many type Long Short-Term Memory (LSTM), a Gated Recurrent Unit (GRU), and a Recurrent Neural Network (RNN) model, or a combination of two or more thereof.

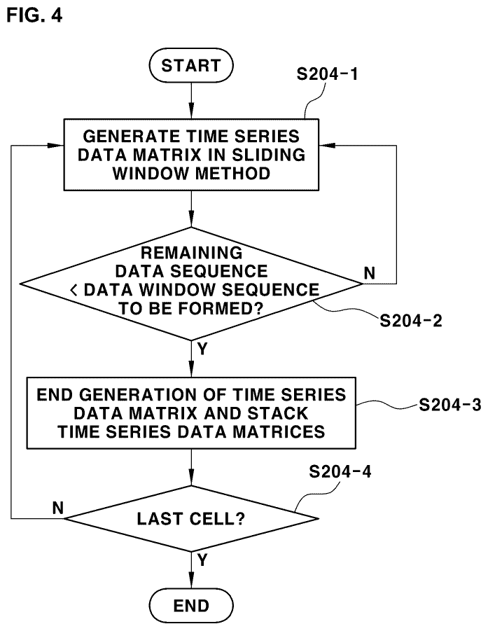

As shown in FIG. 5, the many-to-many type recurrent neural network is a kind of time series estimation model configured so that a plurality of recurrent neural network (RNN) cell layers is stacked to output a result value as output data for each time step. The many-to-many type recurrent neural network, compared to a many-to-one type recurrent neural network with one RNN cell layer, is capable of performing more precise relationship learning between input data (e.g., time series data) and output data, and having a large estimation range for each time step due to a long output data sequence, and thus, may be effectively used as a time series estimation model for estimation of SoH of the supercapacitor.

A long short-term memory (LSTM) cell may be used as the recurrent neural network (RNN) cell that configures the plurality of recurrent neural network (RNN) cell layers included in the many-to-many type recurrent neural network.

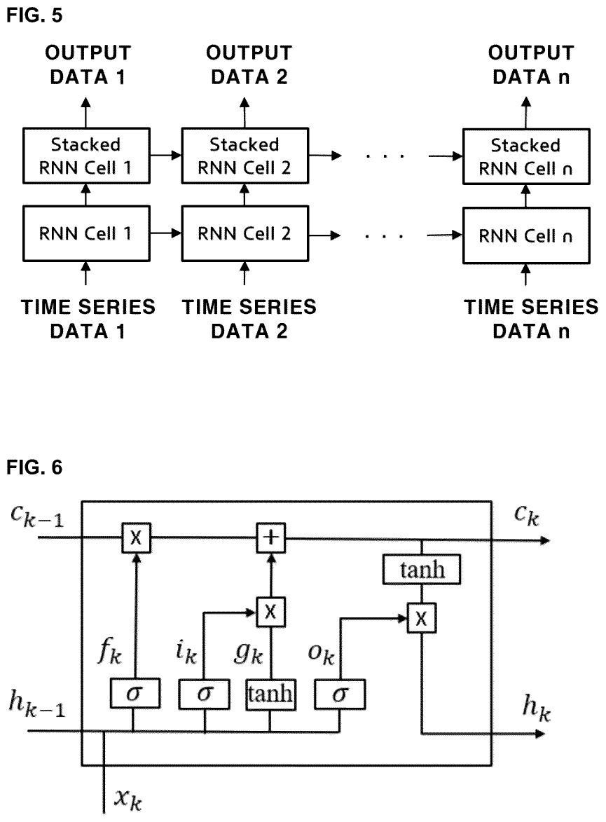

As shown in FIG. 6, the long short-term memory (LSTM) cell includes four gates, i.e., a forget gate (fₖ) into which an input (xₖ), which is current information in a current time step, and a hidden state (hₖ₋₁) in the previous time step are input, respectively, an input gate 1(iₖ), an input gate 2(gₖ), and an output gate (oₖ).

The forget gate (fₖ) is configured to determine how much past information (cₖ₋₁) is reflected in a cell state (cₖ), the input gate 1(iₖ) and the input gate 2(gₖ) are configured to determine how much the current information, i.e., the input (xₖ), is reflected in the cell state (cₖ), and the output gate (oₖ) is configured to determine the hidden state in the current time step.

The long short-term memory (LSTM) cell is a time series estimation model capable of improving a long-term dependency problem that occurs in a basic recurrent neural network, i.e., the problem in which previous information is lost as the length of the input sequence becomes longer, which may be used to construct a neural network model for estimation of SoH of the supercapacitor.

Alternatively, a Gated Recurrent Unit (GRU) cell may be used as the RNN cell that configures the plurality of RNN cell layers included in the many-to-many type RNN.

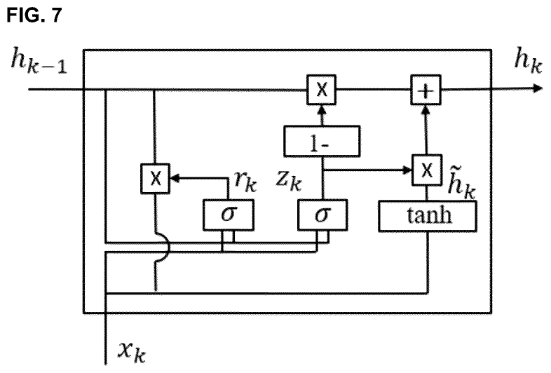

As shown in FIG. 7, the GRU cell has no cell state, unlike the LSTM cell, and is configured to include two gates: a reset gate (rₖ) and an update gate (zₖ) into which an input (xₖ) that is the current information in the current time step is input respectively.

The reset gate (rₖ) is configured to determine how much past information is reflected in the hidden state (hₖ), and the update gate (zₖ) is configured to determine the ratio of reflection of past information and current information.

The GRU cell is a time series estimation model capable of reducing computational complexity due to a smaller number of cell parameters compared to the LSTM cell, and may be used to construct the neural network model for estimation of SoH of the supercapacitor.

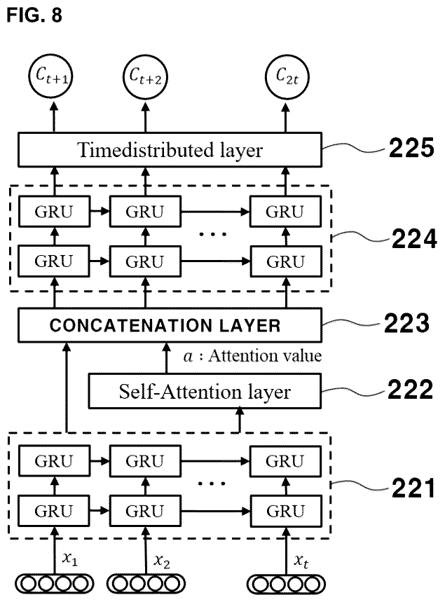

FIG. 8 is a diagram showing a construction example of a neural network model used in a supercapacitor SoH estimation method according to an embodiment of the present disclosure, which shows a time series neural network model that learns an input-output relationship for estimating SoH of a supercapacitor.

As shown in FIG. 8, the neural network model 220 includes a first stacked GRU layer 221, a self-attention layer 222, a concatenation layer 223, a second stacked GRU layer 224, and a time-distributed layer 225.

The first stacked GRU layer 221 has a configuration in which a plurality of gated recurrent units (GRU) is stacked in a recurrent neural network arrangement, and determines a hidden state value for each time step using a first input value (x₁, x₂, . . . , xₜ) including a voltage decrease value (for example, a voltage decrease value for 30 seconds to 40 seconds or a voltage decrease value including IR drop), a discharge current, a temperature, and the like of the supercapacitor.

The self-attention layer 222 calculates a correlation score between hidden state values using the hidden state value for each time step of the first stacked GRU layer 221, and determines an attention value from the calculated correlation score.

The concatenation layer 223 determines a second input value by combining the attention value determined in the self-attention layer with the hidden state values of the first stacked GRU layer.

The second stacked GRU layer 224 has a configuration in which a plurality of gated recurrent units (GRU) is stacked in a recurrent neural network arrangement, and determines the hidden state value for each time step using the second input value.

The time-distributed layer 225 calculates a final result value (Cₜ₊₁, Cₜ₊₂, . . . , C₂ₜ) for estimating SoH of the supercapacitor by multiplying the hidden state value for each time step of the second stacked GRU layer 224 by a weight, and outputs the final result value.

In this way, it is possible to expand an SoH estimation range of the supercapacitor by obtaining the output value for each time step using the time series neural network model that uses the many-to-many type recurrent neural network. Further, by reflecting an autocorrelation score of input sequences to obtain the output value, it is possible to obtain an SoH estimation value of the supercapacitor with higher accuracy.

Hereinafter, a supercapacitor SoH estimation method of an embodiment of the present disclosure based on the above-described configuration is described as follows.

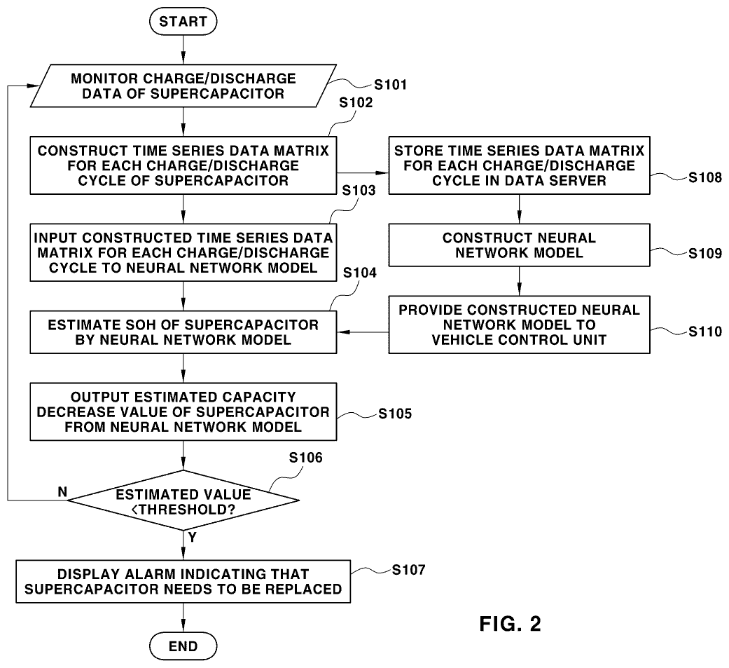

FIG. 2 is a flowchart showing a supercapacitor SoH estimation method according to an embodiment of the present disclosure.

First, while a vehicle is being driven on a road, charge/discharge data of a supercapacitor mounted in a vehicle is monitored by the data detector 100 (S101).

For example, the data detector 100 detects voltage, current, temperature, and the like as charge/discharge data of a supercapacitor mounted in a vehicle and provides the detected charge/discharge data to the vehicle controller 200.

Subsequently, a time series data matrix for each charge/discharge cycle of the supercapacitor is constructed based on the charge/discharge data (voltage, current, temperature, and the like) monitored by the data detector 100, by the data construction unit 210 of the vehicle controller 200 (S102).

Then, the time series data matrix for each charge/discharge cycle constructed by the data construction unit 210 is input to the neural network model 220 of the vehicle controller 200 (S103).

The SoH of the supercapacitor is estimated based on the time series data matrix for each charge/discharge cycle of the supercapacitor constructed by the data construction unit 210, by the neural network model 220 of the vehicle controller 200 (S104).

An estimated capacity decrease value of the supercapacitor is output as an estimation value for the SoH of the supercapacitor, from the neural network model 220 (S105).

Then, the vehicle controller 200 compares the estimated capacity decrease value of the supercapacitor estimated by the neural network model 220 with a threshold (S106).

As a result of the comparison, in a case where the estimated capacity decrease value of the supercapacitor is less than the threshold, it is determined that the supercapacitor needs to be replaced, and the vehicle controller 200 performs control for displaying an alarm indicating that the supercapacitor needs to be replaced on the display device 300 (S107).

In this way, by estimating the SoH of the supercapacitor mounted in the vehicle while the vehicle is being driven and displaying the alarm indicating that the supercapacitor needs to be replaced on the display device 300, a driver may easily recognize that the supercapacitor needs to be replaced.

Further, a process of transmitting the charge/discharge data (voltage, current, temperature, and the like) of the supercapacitor and the time series data matrix for each charge/discharge cycle of the supercapacitor constructed in step S102 to the data server 400 to be stored therein is performed (S108).

Specifically, in order to construct the neural network model 220, the charge/discharge data (voltage, current, temperature, and the like) of the supercapacitor and the time series data matrix for each charge/discharge cycle of the supercapacitor constructed by the data construction unit 210 are transmitted from the vehicle controller 200 to the data server 400 to be stored therein, by a predetermined communication device.

Then, a process of constructing the neural network model 220 based on the charge/discharge data (voltage, current, temperature, and the like) of the supercapacitor and the time series data matrix for each charge/discharge cycle of the supercapacitor stored in the data server 400 is performed by the neural network model constructing processor 410 (S109).

In this way, the neural network model constructing processor 410 constructs the neural network model 220 using the charge/discharge data (voltage, current, temperature, and the like) of the supercapacitor and the time series data matrix for each charge/discharge cycle of the supercapacitor stored in the data server 400. The constructed neural network model may be provided to the vehicle controller 200 through the predetermined communication device (S110).

In step S109, the process of constructing the neural network model 220 by the neural network model constructing processor 410 is as follows.

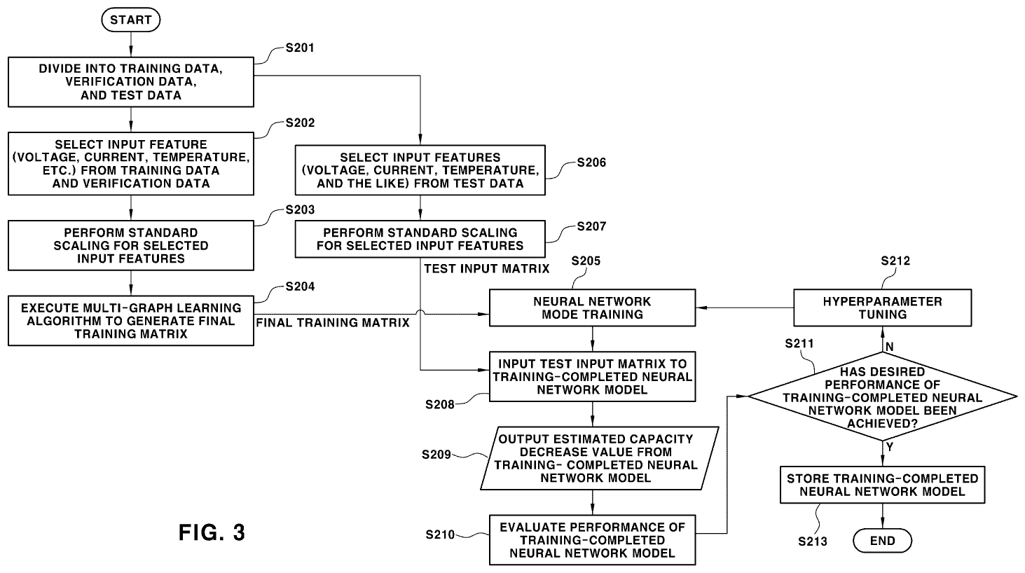

FIG. 3 is a flowchart showing a neural network model construction method used in a supercapacitor SoH estimation method according to an embodiment of the present disclosure.

First, in order to construct the neural network model for estimating SoH of the supercapacitor in the neural network model constructing processor 410, neural network model construction data, i.e., the charge/discharge data (voltage, current, temperature, and the like) of the supercapacitor and the time series data matrix for each charge/discharge cycle of the supercapacitor are divided into training data, verification data, and test data (S201).

Specifically, in a case where the neural network model construction data, i.e., the charge/discharge data (voltage, current, temperature, and the like) of the supercapacitor and the time series data matrix for each charge/discharge cycle of the supercapacitor are provided to the neural network model constructing processor 410 from the data server 400, the neural network model constructing processor 410 divides the charge/discharge data (voltage, current, temperature, and the like) of the supercapacitor and the time series data matrix for each charge/discharge cycle of the supercapacitor into the training data, the verification data, and the test data.

The training data is used to train the neural network model and fit parameters, the verification data is used to tune hyperparameters while verifying whether overfitting or divergence occurs during the training process, and the test data is used to evaluate a final performance of the neural network model.

Then, input features for neural network model training are selected from the training data and the verification data (S202).

For example, the voltage, current, temperature, and the like of the supercapacitor are selected as the input features for neural network model training from the training data and the verification data.

Subsequently, standard scaling is performed for the selected input features (S203).

Specifically, the selected input features (voltage, current, and temperature of the supercapacitor) have different units, and in a case where the difference between the units is large, it has a negative impact on neural network model training. Therefore, a standard scaling process of setting the mean to 0 and the variance to 1 for the selected input features is performed.

Then, a process of executing a multi-graph learning algorithm to generate a final training matrix based on the standard scaled input features is performed (S204).

The process of generating the final training matrix using the multi-graph learning algorithm is as follows.

FIG. 4 shows the multi-graph learning algorithm for constructing the neural network model used in the supercapacitor SoH estimation method according to an embodiment of the present disclosure.

Unlike a general method of implementing a time series model only on one data, the multi-graph learning algorithm forms a window matrix and an answer matrix, which are a kind of time series data matrix, in a graph, and sequentially stacks the matrices formed for each graph to learn multi-graph features.

First, in a first data sequence, a time series data matrix having standard-scaled input features is generated based on a sliding window method (S204-1).

In a case where the generation of the time series data matrix is completed, the size of the remaining data sequence and the size of a data window sequence to be formed are compared (S204-2).

As a result of the comparison, in a case where the size of the remaining data sequence is equal to or greater than the size of the data window sequence to be formed, step S204-1 is repeated.

On the other hand, in a case where the size of the remaining data sequence is smaller than the size of the data window sequence to be formed, the generation of the time series data matrix is terminated, and a time series data matrix stacking process of stacking the generated time series data matrix on a previous time series data matrix generated from a previous data file is performed (S204-3).

In a case where the last cell data for generating the time series data matrix is confirmed (S204-4), the time series data matrix stacking process used as the final training matrix is terminated.

Using the multi-graph learning algorithm including the above-described steps S204-1 to S204-4, a final training matrix in the form of stacked time series data matrices may be generated.

Then, neural network model training for SoH estimation of the supercapacitor is performed using the final training matrix obtained using the multi-graph learning algorithm, i.e., the stacked time series data matrices (S205).

For example, as described above with reference to FIG. 8, training of the neural network model 220 including the first stacked GRU layer 221, the self-attention layer 222, the concatenation layer 223, the second stacked GRU layer 224, and the time-distributed layer 225 may be performed.

Further, by sequentially performing step (S206) of selecting the input features (voltage, current, temperature, and the like of the supercapacitor) for training the neural network model from the test data divided in step S101, and step (S207) of performing the standard scaling for the selected input features, a test input matrix for final performance evaluation of the neural network model may be generated.

Then, in order to verify the performance of the neural network model, training of which was completed in S205, the test input matrix is input to the training-completed neural network model in step S205 (S208), and an estimated capacity decrease value of the supercapacitor is output, as a result of training about the test input matrix, from the training-completed neural network model (S209).

For example, the training-completed neural network model may include the first stacked GRU layer 221, the self-attention layer 222, the concatenation layer 223, the second stacked GRU layer 224, and the time-distributed layer 225, as described with reference to FIG. 8.

Then, based on the estimated capacity decrease value (e.g., capacitance) of the supercapacitor output from the training-completed neural network model, the performance of the training-completed neural network model is evaluated (S210), and it is confirmed whether a desired performance of the training-completed neural network model has been achieved (S211).

The performance evaluation of the training-completed neural network model and the confirmation of whether the desired performance has been achieved may be performed by comparing the capacitance, which is the estimated capacity decrease value of the supercapacitor output from the training-completed neural network model with an actual capacitance of the supercapacitor determined through a predetermined test.

As a result of the comparison, in a case where the capacitance, which is the estimated capacity decrease value of the supercapacitor output from the training-completed neural network model, is different from the actual capacitance of the supercapacitor determined through the predetermined test over a preset error range, hyperparameter tuning is performed (S212), and then, the neural network model training in S205 is performed again.

The hyperparameters refer to variables set in a model to implement an optimal training model.

For example, in the process of training the neural network model, there are various parameters such as an epoch, an optimizer, a learning rate, and a loss function. Since these parameters determine the structure, function, and performance of the neural network model during the training process, optimal neural network model training may be performed again through the process of tuning hyperparameters.

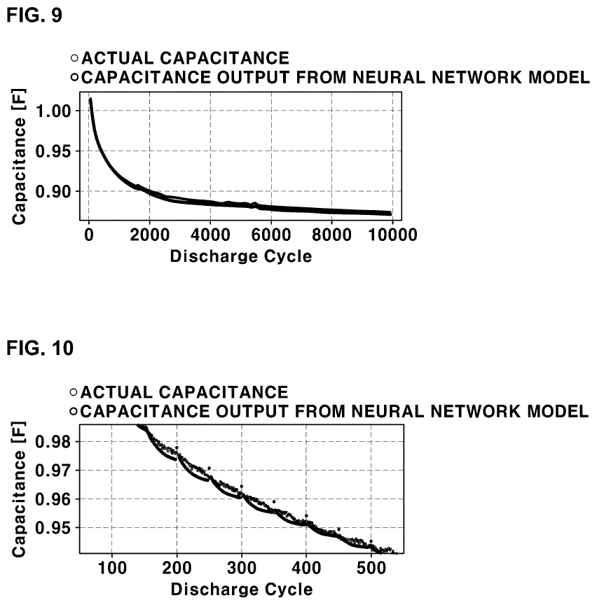

FIG. 9 shows a different comparison result of the capacitance of the supercapacitor output from the training-completed neural network model with the actual capacitance, and FIG. 10 shows a partially enlarged view of the comparison result of the capacitance of the supercapacitor output from the training-completed neural network model with the actual capacitance. As shown in FIGS. 9 and 10, in a case where the capacitance, which is the estimated capacity decrease value of the supercapacitor output from the training-completed neural network model, and the actual capacitance of the supercapacitor determined through the predetermined test are almost identical within the preset error range, it is determined that the desired performance of the training-completed neural network model has been achieved.

Finally, the neural network model constructing processor 410 stores the neural network model for which a determination is made that the desired performance has been achieved (S213), and may provide the stored neural network model to the vehicle controller 200 for SoH estimation of the supercapacitor.

Accordingly, as described in steps S104 and S105, the SoH of the supercapacitor is estimated based on the time series data matrix for each charge/discharge cycle of the supercapacitor in the neural network model 220 of the vehicle controller 200, and the estimated capacity decrease value of the supercapacitor is output as an estimation value of the SoH of the supercapacitor.

As described above, according to the present disclosure, it is possible to accurately estimate the SoH of the supercapacitor using the multi-graph learning algorithm and the many-to-many type recurrent neural network model. Further, in a case where the supercapacitor needs to be replaced after estimation, by displaying the estimated SoH of the supercapacitor on the display device, it is possible for the driver to easily recognize that the supercapacitor needs to be replaced.

According to the present disclosure, it is possible to accurately estimate the SoH of the supercapacitor using the multi-graph learning algorithm and the many-to-many recurrent neural network model, thereby contributing to a stable power operation of the vehicle.

Further, by estimating the SoH of the supercapacitor mounted in the vehicle while the vehicle is being driven, and by displaying the estimation result on the display device when the supercapacitor needs to be replaced, it is possible for the driver to easily recognize that the supercapacitor needs to be replaced.

The disclosure has been described in detail with reference to embodiments thereof. However, it should be appreciated by those having ordinary skill in the art that changes may be made in these embodiments without departing from the principles and spirit of the disclosure, the scope of which is defined in the appended claims and their equivalents.

What is claimed is:

1. A system of supercapacitor state-of-health (SoH) estimation, the system comprising:
a data detector configured to monitor charge-discharge data of a supercapacitor mounted in a vehicle;
a vehicle controller including a data construction unit configured to construct a time series data matrix for each charge-discharge cycle of the supercapacitor based on the charge-discharge data monitored by the data detector, and a neural network model configured to estimate SoH of the supercapacitor using the time series data matrix for each charge-discharge cycle of the supercapacitor output from the data construction unit; and
a display device configured to display an estimation result for the SoH of the supercapacitor estimated by the neural network model of the vehicle controller.

2. The system according to claim 1, further comprising:
a data server configured to store the time series data matrix for each charge-discharge cycle of the supercapacitor transmitted from the vehicle controller; and
a neural network model constructing processor configured to construct a neural network model using the time series data matrix for each charge-discharge cycle of the supercapacitor stored in the data server and to provide the constructed neural network model to the vehicle controller.

3. The system according to claim 1, wherein the neural network model is constructed using at least one of a many-to-many type Long Short-Term Memory (LSTM), a Gated Recurrent Unit (GRU), a Recurrent Neural Network (RNN) model, or a combination thereof.

4. The system according to claim 1, wherein the neural network model comprises:
a first stacked GRU layer having a plurality of gated recurrent units (GRU) stacked in a recurrent neural network arrangement, the first stacked GRU layer configured to determine a hidden state value for each time step using a first input value including a voltage decrease value, a discharge current, and a temperature of the supercapacitor;
a self-attention layer configured to calculate an attention value using the hidden state value for each time step of the first stacked GRU layer;
a concatenation layer configured to determine a second input value by combining the attention value calculated in the self-attention layer with the hidden state values of the first stacked GRU layer;
a second stacked GRU layer having a plurality of gated recurrent units stacked in a recurrent neural network arrangement, the second stacked GRU layer configured to determine a hidden state value for each time step using the second input value; and
a time-distributed layer configured to calculate a final result for estimating the SoH of the supercapacitor by multiplying the hidden state value for each time step of the second stacked GRU layer by a weight and outputs the final result.

5. A method of supercapacitor state-of-health (SoH) estimation, the method comprising:
monitoring, by a data detector, charge-discharge data of a supercapacitor mounted in a vehicle;
constructing, by a data construction unit of a vehicle controller, a time series data matrix for each charge-discharge cycle of the supercapacitor based on the charge-discharge data monitored by the data detector;
estimating, by a neural network model of the vehicle controller, SoH of the supercapacitor based on the time series data matrix for each charge-discharge cycle of the supercapacitor constructed by the data construction unit; and
displaying, on a display device, an estimation result for the SoH of the supercapacitor estimated by the neural network model of the vehicle controller.

6. The method according to claim 5, further comprising:
displaying, when an estimated capacity decrease value is less than a threshold value, an alarm indicating that the supercapacitor needs to be replaced is displayed on the display device, wherein the estimated capacity decrease value is the estimation result for SoH of the supercapacitor estimated by the neural network model of the vehicle controller.

7. The method according to claim 5, further comprising:
storing, in a data server, the time series data matrix for each charge-discharge cycle of the supercapacitor transmitted from the vehicle controller;
constructing, by a neural network model constructing processor, a neural network model based on the time series data matrix for each charge-discharge cycle of the supercapacitor stored in the data server; and
providing the constructed neural network model to the vehicle controller.

8. The method according to claim 7, wherein constructing the neural network model comprises:
dividing neural network model construction data into training data, verification data, and test data;
selecting input features for training the neural network model from the training data and the verification data;
performing standard scaling for the selected input features;
executing a multi-graph learning algorithm for generating a final training matrix based on the standard-scaled input features; and
performing training of the neural network model for estimating the SoH of the supercapacitor using the final training matrix obtained using the multi-graph learning algorithm.

9. The method according to claim 8, wherein constructing the neural network model comprises:
selecting the input features for training the neural network model from the test data;
performing the standard scaling for the selected input features to generate a test input matrix;
inputting the test input matrix to the neural network model for which the training is completed;
outputting, from the training-completed neural network model, an estimated capacity decrease value of the supercapacitor, as a result of training about the test input matrix;
evaluating performance of the training-completed neural network model based on the estimated capacity decrease value of the supercapacitor output from the training-completed neural network model;
confirming whether a desired performance of the training-completed neural network model has been achieved based on the estimated capacity decrease value of the supercapacitor output from the training-completed neural network model; and
storing the training-completed neural network model for which a determination is made that the desired performance has been achieved.

10. The method according to claim 9, wherein evaluating the performance of the training-completed neural network model comprises:
determining that the desired performance of the training-completed neural network model has been achieved, when a difference between a capacitance, which is the estimated capacity decrease value of the supercapacitor output from the training-completed neural network model, and an actual capacitance of the supercapacitor determined through a predetermined test are within a preset error range.

11. The method according to claim 10, wherein when the capacitance, which is the estimated capacity decrease value of the supercapacitor output from the training-completed neural network model, is different from the actual capacitance of the supercapacitor determined through the predetermined test over the preset error range, hyperparameter tuning is performed, and training of the neural network model is performed again.

12. The method according to claim 8, wherein executing the multi-graph learning algorithm comprises:
generating a time series data matrix having standard-scaled input features based on a sliding window method in a first data sequence; and
stacking the generated time series data matrix on a previous time series data matrix generated from a previous data file to generate the final training matrix.

13. The method according to claim 12, wherein after generating the time series data matrix is completed, a size of a remaining data sequence and a size of a data window sequence to be formed are compared, and when the size of the remaining data sequence is equal to or greater than the size of the data window sequence to be formed, generating the time series data matrix is repeated based on the sliding window method.

14. The method according to claim 9, wherein the training-completed neural network model comprises:
a first stacked GRU layer having a plurality of gated recurrent units (GRU) stacked in a recurrent neural network arrangement, the first stacked GRU layer configured to determine a hidden state value for each time step using a first input value including a voltage decrease value, a discharge current and a temperature of the supercapacitor;
a self-attention layer configured to calculate an attention value using the hidden state value for each time step of the first stacked GRU layer;
a concatenation layer configured to determine a second input value by combining the attention value calculated in the self-attention layer with the hidden state values of the first stacked GRU layer;
a second stacked GRU layer having a plurality of gated recurrent units stacked in a recurrent neural network arrangement, the second stacked GRU layer configured to determine a hidden state value for each time step using the second input value; and
a time-distributed layer configured to calculate a final result for estimating the SoH of the supercapacitor by multiplying the hidden state value for each time step of the second stacked GRU layer by a weight and outputs the final result.
